(19) United States
(12) Patent Application Publication
(10) Pub. No.: US 2026/0190646 A1
(43) Pub. Date: Jul. 2, 2026

(54) DISPLAY PANEL

(71) Applicant: LG Display Co., Ltd., Seoul (KR)

(72) Inventors: Harin Kim, Paju-si (KR); Seunghee Nam, Paju-si (KR); Daehee Kim, Goyang-si (KR); Seokwoo Son, Seoul (KR)

(21) Appl. No.: 19/407,766

(22) Filed: Dec. 3, 2025

(30) Foreign Application Priority Data
Dec. 30, 2024 (KR) 10-2024-0200580

(51) Int. Cl. H10K 59/122; H10K 59/131; H10K 59/80

(52) U.S. Cl. CPC H10K 59/122; H10K 59/131; H10K 59/80521

(57) ABSTRACT

In a display panel, a light-emitting element layer, which becomes a path for a horizontal leakage current between adjacent sub-pixels, can be disconnected, thereby reducing the occurrence of the horizontal leakage current, and a second electrode can be used as a common electrode. Accordingly, it is possible to prevent color mixing between adjacent sub-pixels and the occurrence of abnormal light emission.

### CROSS REFERENCE TO RELATED APPLICATION

Pursuant to 35 U.S.C. § 119(a), this application claims the benefit of an earlier filing date and right of priority to Korean Patent Application No. 10-2024-0200580, filed December 30, 2024, the entire contents of which is incorporated herein for all purposes by this reference.

### TECHNICAL FIELD

The present disclosure relates to a display panel.

### BACKGROUND

Display devices are implemented in various forms, such as televisions, monitors, smartphones, tablet PCs, laptops, wearable devices, etc.

Among display devices that display various information as images, an organic light-emitting diode (OLED) display device is a self-luminous element that emits light by itself and has the advantages of a fast response time, high luminous efficiency and brightness, a large viewing angle, and excellent contrast ratio and color reproducibility.

Recently, as users’ demands for high-quality images have increased, development of high-resolution display devices is actively being conducted.

### SUMMARY

According to one implementation of the present disclosure, there is provided a display panel including a substrate on which a plurality of sub-pixels are defined, a planarization layer disposed on the substrate, a first electrode disposed on the planarization layer, a light-emitting element layer disposed on the first electrode, a second electrode disposed on the light-emitting element layer, and a structure disposed between adjacent ones of the plurality of sub-pixels, the structure forming an undercut portion that disconnects the light-emitting element layer, wherein the structure includes a first structure in which a portion of the planarization layer is removed, and a second structure positioned on the first structure and electrically connected to the second electrode.

The first structure may be disposed on the same layer as the planarization layer and formed of the same material as the planarization layer, and the second structure may be disposed on the same layer as the first electrode and formed of the same material as the first electrode.

The first structure and the second structure may be in contact with each other.

The second structure may include a protrusion that extends laterally beyond the first structure, the protrusion being spaced apart from the first structure.

The second electrode may extend continuously along the undercut portion, and the second electrode may be in contact with a lower surface of the protrusion.

The first structure and the second structure each may have a positively tapered shape in which a lateral width decreases in an upward direction.

The first structure may have a positively tapered shape in which a lateral width decreases in an upward direction, and the second structure may have an inversely tapered shape in which the lateral width increases in an upward direction.

The structure may further include a third structure disposed on the second structure, and a dummy second electrode disconnected from the second electrode may be disposed on the third structure.

The structure may further include a third structure disposed on the second structure, and the second electrode may extend continuously along the undercut portion and a perimeter of the structure so as to cover the plurality of sub-pixels.

At the undercut portion, the second electrode may extend further inward into the undercut portion than the light-emitting element layer.

The display panel may further include a power line disposed on the substrate to overlap the undercut portion in a vertical direction, wherein the second electrode may include a connector electrically connected to the power line at the undercut portion.

A portion of the power line may be in contact with the light-emitting element layer, and another portion of the power line may be in contact with the connector.

According to another implementation of the present disclosure, there is provided a display panel including a substrate, a first electrode disposed on the substrate, a light-emitting element layer disposed on the first electrode, a second electrode disposed on the light-emitting element layer, a structure disposed between a plurality of sub-pixels that implement different colors, the structure including a first structure comprising an organic material and a conductive second structure disposed on the first structure, wherein the light-emitting element layer is disconnected by the structure, and the second structure electrically connects the second electrodes of the plurality of sub-pixels that implement different colors to each other.

A lower surface of the second structure may extend laterally beyond an upper surface of the first structure, and the second electrode may extend to be electrically connected to the lower surface of the second structure.

The display panel may further include a planarization layer disposed between the substrate and the first electrode, wherein the first structure may be formed integrally with the planarization layer, and undercut portions are formed on both sides of the first structure by recessing portions of the planarization layer.

The second structure may be disposed on the same layer as the first electrode and formed of the same material as the first electrode.

The display panel may further include a power line disposed between the substrate and the light-emitting element layer, wherein the power line may be electrically connected to the second electrode at the undercut portion.

The organic material may be an insulation material.

According to another implementation of the present disclosure, there is provided a display panel comprising: a substrate on which a plurality of sub-pixels are defined; a planarization layer disposed on the substrate and formed of insulation material; a first electrode disposed on the planarization layer; a light-emitting element layer disposed on the first electrode; a second electrode disposed on the light-emitting element layer; and a structure disposed between adjacent ones of the plurality of sub-pixels, the structure forming an undercut portion that disconnects the light-emitting element layer, wherein the structure includes a first structure which is formed integrally with the planarization layer, and a second structure positioned on the first structure and electrically connected to the second electrode, wherein the undercut portion is formed on both sides of the first structure by recessing a portion of the planarization layer.

According to the implementations of the present disclosure, by allowing the first structure in which a portion of the planarization layer is removed to disconnect the light-emitting element layer and the second structure located on the first structure to electrically connect the second electrode, the light-emitting element layers between adjacent sub-pixels can be disconnected and the second electrodes can be electrically connected.

Accordingly, the light-emitting element layer, which becomes the path for the horizontal leakage current between adjacent sub-pixels, can be disconnected, thereby reducing the occurrence of the horizontal leakage current, and the second electrode can be used as the common electrode. Accordingly, it is possible to prevent color mixing between adjacent sub-pixels and the occurrence of abnormal light emission.

In addition, according to the implementations of the present disclosure, the light-emitting element layer, which becomes the moisture permeation path between adjacent sub-pixels, can be disconnected, thereby enhancing the moisture permeation reliability of the display panel, and the second electrode can be used as the common electrode.

In addition, according to the implementations of the present disclosure, since the first structure and the second structure can be formed by the same process so as to be disposed on the same layer as the planarization layer and the first electrode and be formed of the same material as the planarization layer and the first electrode, there is no need for additional process operations or materials for forming the first structure and the second structure, and thus it is possible to reduce the number of processes and increase the efficiency of the manufacturing process. In this way, it is possible to reduce production energy through process optimization that increases the efficiency of the manufacturing process.

In addition, according to the implementations of the present disclosure, by arranging the first structure and the second structure to come into contact with each other, it is possible to reduce the occurrence of delamination between the structures due to the stacked structure of the plurality of structures formed of different materials, thereby increasing the structural stability of the structure.

In addition, according to the implementations of the present disclosure, the second structure includes a protrusion that protrudes more outward than the first structure and does not come into contact with the first structure, thereby ensuring that the light-emitting element layer is more reliably disconnected and contact between the second structure and the second electrode is more stable.

In addition, according to the implementations of the present disclosure, since the second electrode extending along the undercut portion comes into contact with the lower surface of the protrusion, the second electrode extending upward along the side surface of the first structure can be stably connected to the second structure with a large contact area without disconnection.

In addition, according to the implementations of the present disclosure, the power line can be disposed on the substrate to overlap the undercut portion in the vertical direction so that the second electrode is electrically connected to the power line on the undercut portion, thereby preventing the horizontal leakage current between the sub-pixels and providing the predetermined potential to each sub-pixel. Accordingly, since power can be stably supplied to each sub-pixel, it is possible to improve the image quality and driving stability of the display panel and at the same time, achieve structural simplification.

Specific effects together with the above-described effects are described together with a description of the following detailed matters for carrying out the disclosure.

### BRIEF DESCRIPTION OF THE DRAWINGS

FIG. 1 is a schematic plan view of an example of a display panel.

FIG. 2 is a cross-sectional view of an example of area A of FIG. 1 according to one implementation.

FIG. 3 is a cross-sectional view of an example of area I-I’ of FIG. 2 according to one implementation.

FIG. 4 is a cross-sectional view of an example of area I-I’ of FIG. 2 according to another implementation.

FIG. 5 is an enlarged view of an example of a contact structure of a structure and a second electrode according to one implementation.

FIG. 6 is an enlarged view of an example of a contact structure of a structure and a second electrode according to another implementation.

FIG. 7 is an enlarged view of an example of a contact structure of a structure and a second electrode according to still another implementation.

FIG. 8 is a cross-sectional view of an example of area II-II’ of FIG. 2 according to one implementation.

### DETAILED DESCRIPTION

Implementations of the present disclosure can provide a display panel capable of reducing occurrence of a horizontal leakage current.

In high-resolution display devices, a density of a sub-pixel increases and a spacing between the sub-pixels becomes narrower. This can create a risk of a horizontal leakage current increasing between adjacent sub-pixels, which can distort pixel information and reduce the reliability and image quality of a display panel.

For example, in a white-organic light-emitting diode (OLED) display panel that implements white light, the white light-emitting elements can be formed continuously on the entire front surface of a substrate. In this case, when the sub-pixels are disposed adjacently, color mixing between different colors can occur due to the horizontal leakage current.

In some cases, when one of green light or red light is turned on, both the green and red lights can be simultaneously emitted, or when blue light is turned on, all of the red, green, and blue lights can be simultaneously emitted. As such, when current is applied to a specific sub-pixel, current can flow to adjacent sub-pixels, resulting in unnecessary color mixing or abnormal light emission.

Accordingly, implementations of the present disclosure can provide a display panel with a structure capable of reducing occurrence of the horizontal leakage current.

Implementations of the present disclosure can provide a display panel capable of reducing a horizontal leakage current between adjacent sub-pixels.

Implementations of the present disclosure can also provide a display panel capable of enhancing moisture permeation reliability.

In addition, implementations of the present disclosure can provide a display panel capable of preventing color mixing between adjacent sub-pixels and occurrence of abnormal light emission.

In addition, implementations of the present disclosure can provide a display panel capable of reducing the number of processes without adding additional process operations or materials for forming a structure.

In addition, implementations of the present disclosure can provide a display panel capable of reducing delamination between structures formed in a stacked structure of a plurality of structures.

In addition, implementations of the present disclosure can provide a display panel that can allow a light-emitting element layer to be disconnected and allow a second structure to more stably come into contact with a second electrode.

In addition, implementations of the present disclosure can provide a display panel that can allow a second electrode to be stably connected to a second structure with a larger area without disconnection.

In addition, implementations of the present disclosure can provide a display panel capable of preventing a horizontal leakage current between sub-pixels and applying a predetermined potential to each sub-pixel.

Objects of implementations of the present disclosure are not limited to the above-described objects, and other objects that are not mentioned will be able to be clearly understood by those skilled in the art from the following description.

Advantages and features of the present disclosure and methods for achieving them will become clear by referencing implementations described below in detail in conjunction with the accompanying drawings. However, the present disclosure is not limited to the implementations disclosed below but can be implemented in various different forms, these implementations are merely provided to make the disclosure of the present disclosure complete and fully inform those skilled in the art to which the present disclosure pertains of the scope of the present disclosure, and the present disclosure is only defined by the scope of the appended claims.

Since shapes, sizes, ratios, angles, numbers, etc. disclosed in the drawings for describing the implementations of the present disclosure are illustrative, the present disclosure is not limited to the shown items. The same reference number denotes the same components throughout the disclosure. In addition, in describing the present disclosure, when it is determined that the detailed description of a related known technology may unnecessarily obscure the gist of the present disclosure, the detailed description thereof will be omitted. When “comprises,” “has,” “consists of,” and the like described in the present disclosure are used, other parts may be added unless “only” is used. When a component is expressed in a singular form, it includes a case in which the component is provided as a plurality of components unless specifically stated otherwise.

In construing a component, the component is construed as including a margin of error even when there is no separate explicit description.

When a positional relationship is described, for example, when the positional relationship between two parts is described using “on,” “above,” “under,” “next to,” etc., one or more other parts may be positioned between the two parts unless “immediately” or “directly” is used.

When a temporal relationship is described, for example, when the temporal relationship is described using “after,” “subsequently,” “then,” “before,” etc., it may include a non-consecutive case unless the term “immediately” or “directly” is used.

Although terms such as first and second are used to describe various components, these components are not limited by these terms. The terms are only used to distinguish one component from another. Accordingly, a first component described below may be a second component within the technical spirit of the present disclosure.

Features of various implementations of the present disclosure may be coupled or combined partially or entirely, various technological interworking and driving are made possible, and the implementations may be implemented independently of each other or implemented together in an associated relationship.

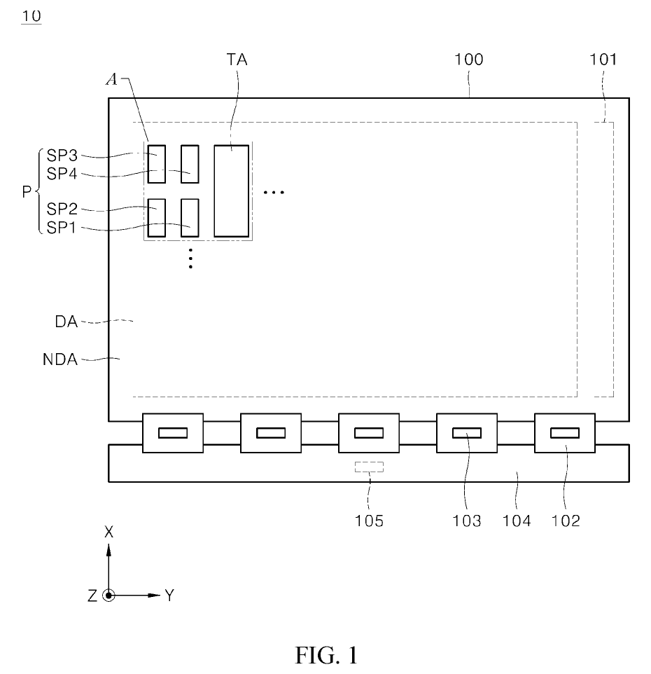

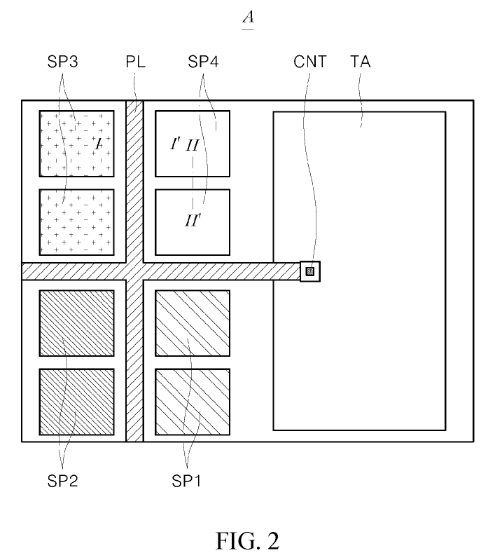

Hereinafter, a display panel and a display device according to one implementation of the present disclosure will be described in detail with reference to FIGS. 1 and 2. A display panel 10 to be described below is described as an organic light-emitting diode display panel as an example, but is not limited thereto. In addition, the display panel 10 according to the implementation of the present disclosure may be implemented as various types of display devices, and the type of the display device is not particularly limited.

The display panel 10 may include a substrate 100 including a display area DA and a non-display area NDA surrounding the display area DA. The display panel 10 may include the substrate 100, a source driving integrated circuit (IC) 103, a flexible film 102, a circuit board 104, and a timing controller 105.

The display area DA on the substrate 100 may include a plurality of sub-pixels SP1, SP2, and SP3 each formed in one of areas defined by the intersection of a plurality of data lines extending in a first direction and a plurality of gate lines extending in a second direction intersecting the first direction. The first direction described in the present disclosure may be an X-axis direction, the second direction may be a Y-axis direction, and a Z-axis direction may be a direction perpendicular to the X-axis and the Y-axis. In addition, in the present disclosure, an example in which one pixel P is composed of a first sub-pixel SP1, a second sub-pixel SP2, a third sub-pixel SP3, and a fourth sub-pixel SP4 will be described, but the present disclosure is not limited thereto.

For example, each sub-pixel SP1, SP2, SP3, or SP4 may be implemented to emit a different color for each sub-pixel, such as red, green, blue, or white light. Hereinafter, the first sub-pixel SP1 may be a red sub-pixel implementing red, the second sub-pixel SP2 may be a green sub-pixel implementing green, the third sub-pixel SP3 may be a blue sub-pixel implementing blue, and the fourth sub-pixel SP4 may be a white sub-pixel implementing white. The plurality of sub-pixels SP1, SP2, SP3, and SP4 may be disposed in a form of a matrix arranged in a plurality of rows and columns.

A transmissive part TA may be disposed on one side of the plurality of sub-pixels. The transmissive part TA may also be referred to as a transparent part. The transmissive parts TA and the plurality of sub-pixels may be disposed in the form of a matrix alternately in the first direction and the second direction. An area in which sub-pixels are disposed other than the transmissive part TA may be referred to as a light-emitting part or a pixel part.

A gate driver 101 located on one side or both sides of the display area DA may be disposed on the non-display area NDA on the substrate 100. The gate driver 101 may be implemented in a gate-in-panel (GIP) manner. The gate driver 101 may generate gate signals to gate lines according to a gate control signal received from the timing controller 105.

The source driving IC 103 may receive digital video data and a source control signal from the timing controller 105. The source driving IC 103 may convert the digital video data into analog data voltages according to the source control signal and supply the analog data voltages to data lines. The source driving IC 103 may be manufactured as a driving chip in a chip on film (COF) or chip on plastic (COP) manner and mounted on a plurality of flexible films 102. The circuit board 104 may be attached to the plurality of flexible films 102. A plurality of circuits implemented as chips such as the timing controller 105 may be mounted on the circuit board 104.

The timing controller 105 may receive the digital video data and timing signals from an external system board through a cable of the circuit board 104. The timing controller 105 may supply the gate control signal for controlling the operation timing of the gate driver 101 and the source control signal for controlling the source driving IC 103 based on the timing signals.

Meanwhile, the source driving IC 103 may apply driving voltages such as a high-potential voltage VDD, a low-potential voltage VSS, etc. to the pixel P. For example, a power line PL may be disposed along an edge of the display area DA excluding one side of the non-display area NDA on which the source driving IC 103 is disposed. The power line PL may be a low-potential voltage line that may apply the low-potential voltage VSS to a cathode electrode of the pixel P. In this case, power applied to the power line PL may be a common power that is supplied in common to a plurality of sub-pixels.

In addition, the power line PL may be disposed within the display area DA. For example, the power line PL located on the non-display area NDA may extend to the inside of the display area DA. In addition, a power connection line electrically connected to the power line PL located on the non-display area NDA may extend to the inside of the display area DA. In this way, since the power connection line extending to the inside of the display area DA is electrically connected to the power line PL, the power connection line may also serve as a low-potential voltage line that actually applies the low-potential voltage VSS.

The power line PL disposed within the display area DA may extend to pass through a space between the sub-pixels. The power line PL may extend to pass through the space between the sub-pixels that implement different colors. For example, the power line PL may extend to pass through a space between the third sub-pixel SP3 and the fourth sub-pixel SP4 and to pass through a space between the first sub-pixel SP1 and the second sub-pixel SP2. In addition, the power line PL may extend to pass through a space between the second sub-pixel SP2 and the third sub-pixel SP3 and to pass through a space between the first sub-pixel SP1 and the fourth sub-pixel SP4. Accordingly, the power line PL may extend in the first direction and the second direction intersecting each other so as to pass through boundaries between the sub-pixels that implement different colors.

According to one implementation of the present disclosure, a pair of sub-pixels that implement the same color may be disposed adjacent to each other. The power line PL may not extend to pass through a space between a pair of sub-pixels that implement the same color. Accordingly, sub-pixels that implement different colors and are disposed adjacent to each other may be disposed with their areas divided by the power line PL, but areas of sub-pixels that implement the same color and are disposed adjacent to each other may not be divided by the power line PL.

A contact part CNT electrically connected to the power line PL may be disposed on the transmissive part TA. The contact part CNT may be a point that electrically connects the power line PL extending to pass through the space between sub-pixels within the display area DA to the power line PL located on the non-display area NDA.

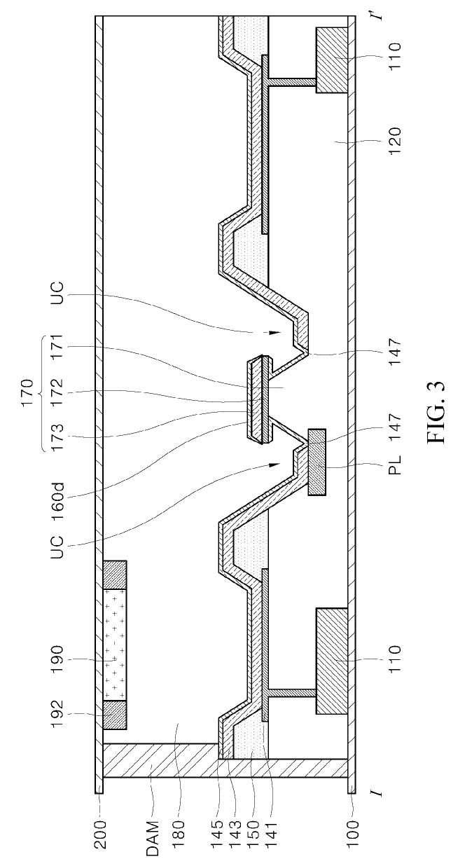

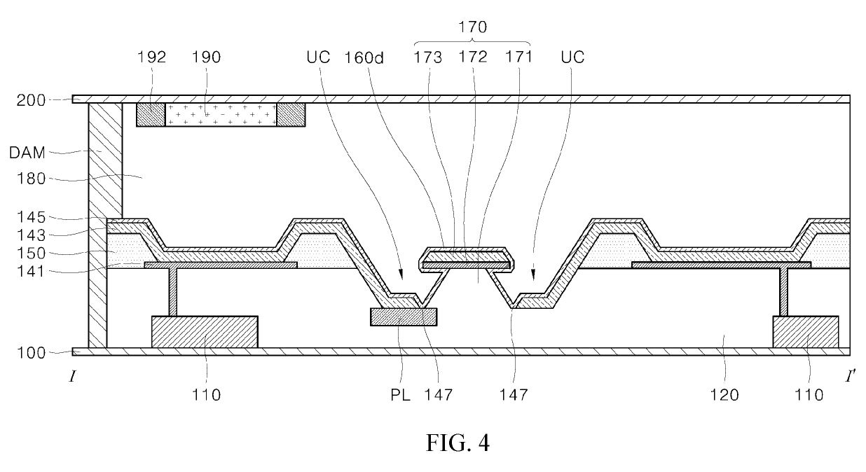

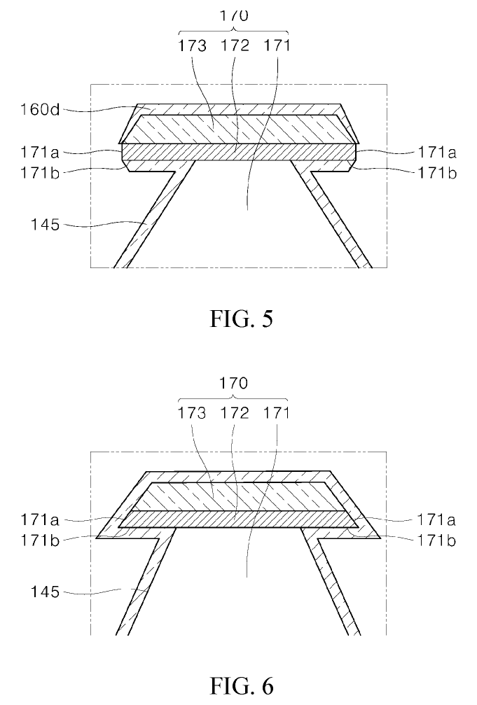

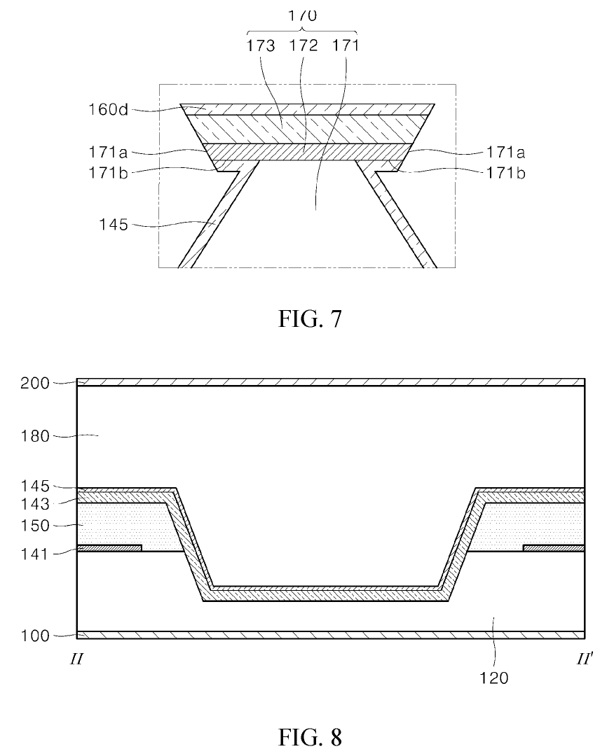

Hereinafter, a stacked structure of the display panel 10 according to one implementation of the present disclosure will be described with further reference to FIGS. 3 to 8. FIGS. 3 and 4 are cross-sectional views of area I-I’ of FIG. 2 according to different implementations. FIGS. 5 and 7 are enlarged views of a contact structure of a structure and a second electrode according to different implementations. FIG. 8 is a cross-sectional view of area II-II’ of FIG. 2 according to one implementation.

The display panel 10 may include the lower substrate 100. For example, the lower substrate 100 may be formed of glass, but is not limited thereto. The lower substrate 100 may be formed of plastic such as polyimide, or formed of a semiconductor material such as a silicon wafer. For example, the lower substrate 100 may be a single-crystal silicon wafer formed by growing single-crystal silicon (Si) or a wafer formed of various semiconductor materials.

A circuit part 110 may be disposed on the lower substrate 100. The circuit part 110 may be disposed on each of the sub-pixels SP1, SP2, SP3, and SP4 included in the display panel 10. The circuit part 110 may be electrically connected to a light-emitting element layer disposed on the circuit part 110. The circuit part 110 may include various circuit-related elements including various signal lines such as gate lines, data lines, thin film transistors, storage capacitors, etc. The thin film transistor may include a switching thin film transistor, a driving thin film transistor, a sensing thin film transistor, etc., but is not limited thereto and may also include a complementary metal oxide semiconductor (CMOS) transistor.

For example, when the circuit part 110 is a thin film transistor, the circuit part 110 may include an active layer, a source electrode, a drain electrode, and a gate electrode. In this case, a buffer layer may be disposed between the lower substrate 100 and the thin film transistor. In addition, a gate insulating layer may be disposed between the active layer and the gate electrode. In addition, an interlayer insulating layer may be disposed on the thin film transistor. In this case, the buffer layer and the interlayer insulating layer may be disposed to cover the entire front surface of the lower substrate 100 across the plurality of sub-pixels. The buffer layer, the gate insulating layer, and the interlayer insulating layer may be inorganic insulating layers. For example, the inorganic insulating layer may include silicon oxide (SiOₓ) or silicon nitride (SiNₓ), but is not limited thereto.

The power line PL may be disposed on the circuit part 110. The power line PL may be disposed on the interlayer insulating layer. The power line PL may be disposed to be spaced a predetermined distance from the circuit part 110 in a horizontal direction. As described with reference to FIG. 2, the power line PL may be disposed to pass through the boundary between adjacent sub-pixels.

A planarization layer 120 may be disposed on the circuit part 110 and the power line PL. The planarization layer 120 may be disposed to cover the entire front surface of the lower substrate 100. The planarization layer 120 may reduce a step difference of the lower structure. Accordingly, the planarization layer 120 may be referred to as an overcoat layer. The planarization layer 120 may include an organic material. For example, the planarization layer 120 may include an organic material such as a photoacryl, a polyimide, a benzocyclobutene-based resin, an acrylate, etc. For example, the planarization layer 120 may be formed of insulation material. The insulation material may be an organic material.

A first electrode 141 may be disposed on the planarization layer 120. The first electrode 141 may be referred to as a pixel electrode. In addition, the first electrode 141 may also be referred to as an anode electrode. The first electrode 141 may be electrically connected to the circuit part 110 through contact holes formed in the planarization layer 120. For example, the first electrode 141 may include magnesium (Mg), calcium (Ca), aluminum (Al), silver (Ag), or an alloy thereof, but is not limited thereto.

The first electrodes 141 disposed between adjacent sub-pixels may be disposed to be spaced apart from each other. A bank layer 150 may be disposed on the first electrode 141. The bank layer 150 may be formed to cover an end of the first electrode 141, thereby preventing current from being concentrated on the end of the first electrode 141. In addition, the bank layer 150 may define a boundary of a light-emitting area in which light is actually emitted. Accordingly, an area in which the bank layer 150 is patterned and removed so that an upper surface of the first electrode 141 is exposed may be defined as the light-emitting area.

The bank layer 150 may include an organic material. For example, the bank layer 150 may include an organic material such as photoacryl, polyimide, a benzocyclobutene-based resin, acrylate, etc. Accordingly, the bank layer 150 may be referred to as an organic insulating layer. In addition, the bank layer 150 may be implemented as a fence. In addition, the bank layer 150 may be implemented as a black bank including a black material.

A light-emitting element layer 143 may be disposed on the first electrode 141. The light-emitting element layer 143 disposed on the first electrode 141 may be formed over the entire front surface of the lower substrate 100 to cover adjacent sub-pixels in addition to the bank layer 150. The light-emitting element layer 143 may be formed as a single stack. However, the present disclosure is not limited thereto, and the light-emitting element layer 143 may have a tandem structure in which two stacks including a first stack, a charge generation layer CGL, and a second stack are stacked, or a tandem structure in which three or more stacks are stacked.

For example, when the light-emitting element layer 143 includes the first stack, the charge generation layer, and the second stack, the first stack may include a hole injecting layer (HIL), a hole transporting layer (HTL), an emitting material layer (EML), and an electron transporting layer (ETL), and the emitting material layer (EML) of the first stack may emit one of red light, green light, blue light, and yellow light. The charge generation layer may include a negative type (N-type) charge generation layer for supplying electrons to the first stack, and a positive type (P-type) charge generation layer for supplying holes to the second stack. The second stack includes a hole transporting layer (HTL), an emitting material layer (EML), an electron transporting layer (ETL), and an electron injecting layer (EIL), and the emitting material layer (EML) of the second stack may emit one of red light, green light, blue light, and yellow light. Since the emitting material layer (EML) of the first stack and the emitting material layer (EML) of the second stack may emit light of different colors, the light-emitting element layer 143 including the first stack and the second stack may emit white light.

A second electrode 145 may be disposed on the light-emitting element layer 143. The second electrode 145 may be formed over the entire front surface of the lower substrate 100 so as to be electrically connected to the light-emitting element layer 143 formed to cover all sub-pixels. The second electrode 145 may also be referred to as a common electrode. In addition, the second electrode 145 may be referred to as a cathode electrode. For example, the second electrode 145 may include a transparent conductive material such as indium tin oxide (ITO), indium zinc oxide (IZO), and zinc oxide (ZnO).

The first electrode 141, the light-emitting element layer 143, and the second electrode 145, which are sequentially stacked on the light-emitting area defined by the bank layer 150, may emit light in an area in which they come into contact with and overlap each other. The light emitted from the light-emitting area may be white light. The light emitted from the light-emitting area may be emitted toward a color filter layer 190 disposed on an upper portion of the light-emitting area.

An encapsulation layer 180 that blocks external moisture and oxygen may be disposed on the second electrode 145. For example, the encapsulation layer 180 may include an organic material. A dam DAM formed to surround the encapsulation layer 180 may be disposed outside the encapsulation layer 180 to prevent an overflow of the encapsulation layer 180.

The color filter layer 190 may be disposed on the encapsulation layer 180. The color filter layer 190 may be disposed to overlap the light-emitting area in a vertical direction. The color filter layer 190 may be formed to implement different colors for each sub-pixel. For example, a first color filter layer of a red color may be disposed in the first sub-pixel SP1, a second color filter layer of a green color may be disposed in the second sub-pixel SP2, and a third color filter layer of a blue color may be disposed in the third sub-pixel SP3. When a white sub-pixel is additionally disposed, a separate color filter layer may not be disposed in the white sub-pixel.

In addition, a black matrix layer 192 may be disposed on both sides of the color filter layer. The black matrix layer 192 may be located on the boundary of the light-emitting area. The black matrix layer 192 can prevent light that is emitted from the light-emitting area and passes through the color filter layer 190 from being mixed with the color of the adjacent sub-pixel.

An upper substrate 200 may be disposed on the color filter layer 190 and the encapsulation layer 180. For example, the upper substrate 200 may be formed of glass, but is not limited thereto.

Meanwhile, a structure 170 forming an undercut portion UC may be disposed between a plurality of adjacent sub-pixels. The structure 170 may include a first structure 171 and a second structure 172 disposed on the first structure 171.

Based on the cross-sectional view of FIG. 3, the undercut portion UC formed by removing a portion of the planarization layer 120 may be formed on both sides of the structure 170. The undercut portion UC may be formed in a form in which a portion of the planarization layer 120 is recessed downward. The first structure 171 may be a pattern shape of the planarization layer 120 adjacent to the undercut portion UC that remains except for the planarization layer 120 removed to form the undercut portion UC. Accordingly, the first structure 171 may be disposed on the same layer as the planarization layer 120 and formed of the same material as the planarization layer 120. That is, the first structure 171 may be formed integrally with the planarization layer 120. In some implementations, the first structure 171 may be formed of insulation material. The insulation material may be an organic material.

The second structure 172 that is disposed on the same layer as the first electrode 141 and is formed of the same material as the first electrode 141 may be disposed on the first structure 171. The second structure 172 may be disposed to be spaced a predetermined distance from the first electrode 141 in the horizontal direction. That is, the second structure 172 may be spaced apart from the first electrode 141 so as to be disconnected.

The first structure 171 and the second structure 172 may be formed by the same process as the process in which the planarization layer 120 and the first electrode 141 are formed. An upper surface of the first structure 171 formed in this way may come into contact with a lower surface of the second structure 172.

Referring further to FIG. 5 that is an enlarged view of the structure 170 of FIG. 3, the second structure 172 may include a protrusion 171a that protrudes more outward than the first structure 171 and does not come into contact with the first structure 171. That is, a length of the lower surface of the second structure 172 may extend to be larger than the upper surface of the first structure 171. Accordingly, a pair of protrusions 171a of the second structure 172 may be formed to protrude at both sides of the first structure 171 based on the cross-sectional view of FIG. 5.

The first structure 171 may have a positively tapered shape in which a lateral width decreases upward. In addition, the second structure 172 may also have a positively tapered shape in which the lateral width decreases from the bottom to the top. However, the present disclosure is not limited thereto, and the constant lateral width of the second structure 172 may be maintained from the bottom to the top. In addition, the second structure 172 may have a positively tapered shape in which the lateral width decreases from the bottom to the top, but a side surface of the second structure 172 may be formed at a nearly vertical angle.

For example, the second structure 172 located between adjacent sub-pixels may be exposed to the outside through an etching process of the bank layer 150, and a double-layer structure of the first structure 171 and the second structure 172 may be formed through a process of over-etching the planarization layer 120 located below the second structure 172. For example, the undercut portion UC of the structure 170 may be formed by a method of wet-etching the bank layer 150 and the planarization layer 120 through a high-concentration buffered oxide etchant (BOE) solution material. The second structure 172 disposed on the first structure 171 may be formed to have a structure like a kind of eaves.

The structure 170 according to the implementation of the present disclosure may further include a third structure 173 in addition to the first structure 171 and the second structure 172. The third structure 173 may be additionally disposed on the second structure 172. The third structure 173 may be disposed on the same layer as the light-emitting element layer 143 and formed of the same material as the light-emitting element layer 143. The third structure 173 may be disposed to be spaced a predetermined distance from the light-emitting element layer 143 in the horizontal direction. That is, the second structure 172 may be spaced apart from the light-emitting element layer 143 so as to be disconnected.

As described above, the light-emitting element layer 143 and the second electrode 145 may extend to cover the entire front surface of the lower substrate 100. However, the light-emitting element layer 143 may be disconnected at the undercut portion UC formed by the structure 170. For example, the light-emitting element layer 143 may extend to cover a portion of the undercut portion UC but extend only to the extent that does not cover a side surface of the first structure 171. That is, a length of the light-emitting element layer 143, which extends outward more than the side surface of the first structure 171, may be disconnected.

The power line PL may be disposed below the undercut portion UC. The power line PL may be disposed to overlap the undercut portion UC in the vertical direction. For example, the undercut portion UC may be etched to be recessed downward to the extent that the upper surface of the power line PL is exposed. Accordingly, the light-emitting element layer 143 extending to a portion of the inside of the undercut portion UC may be disposed to cover a portion of the upper surface of the power line PL. The light-emitting element layer 143 may come into contact with a portion of the upper surface of the power line PL at the undercut portion UC. However, since the light-emitting element layer 143 does not cover the entirety of the upper surface of the power line PL and extends to cover only a portion thereof, a portion of the upper surface of the power line PL may still be exposed to the outside.

The second electrode 145 may extend to cover the entire front surface of the lower substrate 100. For example, the second electrode 145 may be formed using a sputtering process. As a material forming the second electrode 145, a material having a higher step coverage than a material forming the light-emitting element layer 143 is preferably used. For example, an IZO material has much better step coverage than the material forming the light-emitting element layer 143. Accordingly, the second electrode 145 may be formed to extend inward in the undercut portion UC more than the light-emitting element layer 143. In this case, the sputtering process may use a mobile sputtering process in which a sputtering target moves during the process. Accordingly, thicknesses of the second electrodes 145 formed on the undercut portions UC located on both sides of the structure 170 may be formed differently and asymmetrically, but due to the high step coverage of the material forming the second electrode 145, the second electrodes 145 may not be disconnected at the undercut portions UC located on both sides.

In this way, since the second electrode 145 may be formed to cover the undercut portion UC of the planarization layer 120, it is possible to minimize the exposure of the planarization layer 120, which exhibits very vulnerable characteristics when exposed to the outside, thereby preventing the occurrence of problems such as dark spots that may occur at the undercut portion UC and increasing the reliability of the display panel 10.

For example, the second electrode 145 may be formed to extend along the side surface of the first structure 171 through the undercut portion UC and to extend continuously without interruption at least to a lower surface 171b of the protrusion 171a of the second structure 172. That is, the second electrode 145 may come into contact with the lower surface 171b of the protrusion 171a of the second structure 172. Since the second structure 172 is formed of the same material as the first electrode 141, the second structure 172 may be formed of a conductive material. Accordingly, the second electrode 145 in contact with the second structure 172 may be electrically connected to the second structure 172.

For example, since the lower surface 171b of the protrusion 171a located on one side of the second structure 172 may be electrically connected to the second electrode 145 extending from the third sub-pixel SP3 and the lower surface 171b of the protrusion 171a located on the other side of the second structure 172 may be electrically connected to the second electrode 145 extending from the fourth sub-pixel SP4, the second structure 172 may serve as a conductive medium that electrically connects the second electrodes 145 passing through the sub-pixels that implement different colors.

Meanwhile, since the second electrode 145 extends inward from the undercut portion UC beyond a point at which the light-emitting element layer 143 is disconnected at the undercut portion UC, the second electrode 145 may come into contact with a portion of the power line PL that is not covered by the light-emitting element layer 143. That is, the second electrode 145 may extend in the undercut portion UC in a direction in which the structure 170 is located more than the light-emitting element layer 143.

In this case, an area of the second electrode 145 in contact with the power line PL may be defined as a connector 147. Accordingly, since the connector 147 of the second electrode 145 is electrically connected to the power line PL at the undercut portion UC, a voltage of the power line PL may be applied to the second electrode 145.

In this way, since the second electrode 145 maintains electrical connection between sub-pixels that implement different colors through the second structure 172 and is electrically connected to the power line PL at the undercut portion UC to receive voltage, the second electrode 145 may serve as a common electrode.

Referring to FIG. 5, which is an enlarged view of the structure 170 of FIG. 3, a dummy second electrode 160d may be disposed on the third structure 173. The dummy second electrode 160d may be a dummy electrode that is formed as the same layer as the second electrode 145 and formed of the same material as the second electrode 145, but is not electrically connected to the second electrode 145. That is, the second electrode 145 may not extend to the side surface of the second structure 172 and may be disconnected at the lower surface 171b of the protrusion 171a of the second structure 172. In addition, the dummy second electrode 160d may extend to cover an upper surface or the upper and side surfaces of the third structure 173, but may not extend to the side surface of the second structure 172. In this case, the side surface of the second structure 172 may be formed to have a nearly vertical positively tapered shape.

In addition, referring to FIG. 6, which is an enlarged view of the structure 170 of FIG. 4 as another implementation, the second electrode 145 may extend along the side surface of the first structure 171, pass through the lower surface 171b of the protrusion 171a of the second structure 172, and cover the side surfaces of the second structure 172 and the side surfaces and the upper surface of the third structure 173. That is, the second electrode 145 may continuously extend along the perimeter of the structure 170 without being disconnected from the structure 170 so that electrical connection between adjacent sub-pixels may be maintained. Accordingly, the second electrode 145 may continuously extend along the undercut portion UC and the perimeter of the structure 170 to cover the plurality of sub-pixels.

In this way, when the second electrode 145 is not disconnected by the structure 170, a movement path of charges may extend, thereby reducing the horizontal leakage current between adjacent sub-pixels.

In addition, referring to FIG. 7 as still another implementation, the second structure 172 may be formed to have a inversely tapered shape in which a lateral width increases in upward direction. In addition, the third structure 173 disposed on the second structure 172 may also be formed to have a inversely tapered shape in which the lateral width increases upward. The dummy second electrode 160d may be disposed on the third structure 173. The dummy second electrode 160d may be a dummy electrode that is formed as the same layer as the second electrode 145 and formed of the same material as the second electrode 145, but is not electrically connected to the second electrode 145. That is, the second electrode 145 may not extend to the side surface of the second structure 172 and may be disconnected at the lower surface 171b of the second structure 172. In addition, the dummy second electrode 160d may extend to cover the upper surface of the third structure 173, but may not extend to the side surface of the third structure 173. As the second structure 172 is formed to have a inversely tapered shape in this way, the second electrode 145 can be more reliably disconnected from the structure 170.

Referring to FIG. 8, a separate structure may not be disposed between sub-pixels that implement the same color. Since there is no concern about color mixing in the case of sub-pixels that implement the same color, even when the horizontal leakage current occurs, it may not actually lead to a problem with the reliability of the display panel 10.

The display panel 10 according to the implementation of the present disclosure may have the following advantageous effects.

According to the implementations of the present disclosure, by allowing the first structure 171 in which a portion of the planarization layer 120 is removed to disconnect the light-emitting element layer 143 and the second structure 172 located on the first structure 171 to electrically connect the second electrode 145, the light-emitting element layers 143 between adjacent sub-pixels can be disconnected and the second electrodes can be electrically connected.

Accordingly, the light-emitting element layer 143, which becomes the path for the horizontal leakage current between adjacent sub-pixels, can be disconnected, thereby reducing the occurrence of the horizontal leakage current, and the second electrode 145 can be used as the common electrode. Accordingly, it is possible to prevent color mixing between adjacent sub-pixels and the occurrence of abnormal light emission.

In addition, according to the implementations of the present disclosure, the light-emitting element layer 143, which becomes the moisture permeation path between adjacent sub-pixels, can be disconnected, thereby enhancing the moisture permeation reliability of the display panel, and the second electrode 145 can be used as the common electrode.

In addition, according to the implementations of the present disclosure, since the first structure 171 and the second structure 172 can be formed by the same process so as to be disposed on the same layer as the planarization layer 120 and the first electrode 141 and be formed of the same material as the planarization layer 120 and the first electrode 141, there is no need for additional process operations or materials for forming the first structure 171 and the second structure 172, and thus it is possible to reduce the number of processes and increase the efficiency of the manufacturing process.

In addition, according to the implementations of the present disclosure, by arranging the first structure 171 and the second structure 172 to come into contact each other, it is possible to reduce the occurrence of delamination between the structures due to the stacked structure of the plurality of structures formed of different materials, thereby increasing the structural stability of the structure.

In addition, according to the implementations of the present disclosure, since the second electrode 145 extending along the undercut portion UC comes into contact with the lower surface 171b of the protrusion 171a of the second electrode 145, the second electrode 145 extending upward along the side surface of the first structure 171 can be stably connected to the second structure 172 with a large contact area without disconnection.

In addition, according to the implementations of the present disclosure, the power line PL can be disposed on the substrate to overlap the undercut portion UC in the vertical direction so that the second electrode 145 is electrically connected to the power line PL on the undercut portion, thereby preventing the horizontal leakage current between the sub-pixels and providing the predetermined potential to each sub-pixel. Accordingly, since power can be stably supplied to each sub-pixel, it is possible to improve the image quality and driving stability of the display panel 10 and at the same time, achieve structural simplification.

Although the implementations of the present disclosure have been described in more detail with reference to the accompanying drawings, the present disclosure is not necessarily limited to these implementations, and various modifications may be carried out without departing from the technical spirit of the present disclosure. Accordingly, the implementations disclosed in the present disclosure are not intended to limit the technical spirit of the present disclosure, but is intended to describe the same, and the scope of the technical spirit of the present disclosure is not limited by these implementations. Accordingly, it should be understood that the above-described implementations are illustrative and not restrictive in all aspects.

What is claimed is:

1. A display panel comprising:
a substrate on which a plurality of sub-pixels are defined;
a planarization layer disposed on the substrate;
a first electrode disposed on the planarization layer;
a light-emitting element layer disposed on the first electrode;
a second electrode disposed on the light-emitting element layer; and
a structure disposed between adjacent sub-pixels of the plurality of sub-pixels, the structure forming an undercut portion that disconnects the light-emitting element layer,
wherein the structure includes a first structure in which a portion of the planarization layer is removed, and a second structure positioned on the first structure and electrically connected to the second electrode.

2. The display panel of claim 1, wherein the first structure is disposed on the same layer as the planarization layer and is formed of the same material as the planarization layer, and
the second structure is disposed on the same layer as the first electrode and is formed of the same material as the first electrode.

3. The display panel of claim 1, wherein the first structure and the second structure are in contact with each other.

4. The display panel of claim 1, wherein the second structure includes a protrusion that extends laterally beyond the first structure, the protrusion being spaced apart from the first structure.

5. The display panel of claim 4, wherein the second electrode extends continuously along the undercut portion, and
the second electrode is in contact with a lower surface of the protrusion.

6. The display panel of claim 1, wherein the first structure and the second structure each have a positively tapered shape in which a lateral width decreases in an upward direction.

7. The display panel of claim 1, wherein the first structure has a positively tapered shape in which a lateral width decreases in an upward direction, and the second structure has an inversely tapered shape in which the lateral width increases in an upward direction.

8. The display panel of claim 1, wherein the structure further includes a third structure disposed on the second structure, and
a dummy second electrode disconnected from the second electrode is disposed on the third structure.

9. The display panel of claim 1, wherein the structure further includes a third structure disposed on the second structure, and
the second electrode extends continuously along the undercut portion and a perimeter of the structure and covers the plurality of sub-pixels.

10. The display panel of claim 1, wherein at the undercut portion, the second electrode extends further inward into the undercut portion than the light-emitting element layer.

11. The display panel of claim 1, further comprising a power line disposed on the substrate to overlap the undercut portion in a vertical direction,
wherein the second electrode includes a connector electrically connected to the power line at the undercut portion.

12. The display panel of claim 11, wherein a portion of the power line is in contact with the light-emitting element layer, and another portion of the power line is in contact with the connector.

13. A display panel comprising:
a substrate;
a first electrode disposed on the substrate;
a light-emitting element layer disposed on the first electrode;
a second electrode disposed on the light-emitting element layer; and
a structure disposed between a plurality of sub-pixels that implement different colors, the structure including a first structure comprising an organic material and a second structure that is conductive and is disposed on the first structure,
wherein the light-emitting element layer is disconnected by the structure, and
the second structure is electrically connected to the second electrode between the plurality of sub-pixels that implement different colors.

14. The display panel of claim 13, wherein a lower surface of the second structure extends laterally beyond an upper surface of the first structure, and
the second electrode extends to be electrically connected to the lower surface of the second structure.

15. The display panel of claim 13, further comprising a planarization layer disposed between the substrate and the first electrode,
wherein the first structure is formed integrally with the planarization layer, and
undercut portions are formed on both sides of the first structure by recessing portions of the planarization layer.

16. The display panel of claim 13, wherein the second structure is disposed on the same layer as the first electrode and is formed of the same material as the first electrode.

17. The display panel of claim 15, further comprising a power line disposed between the substrate and the light-emitting element layer,
wherein the power line is electrically connected to the second electrode at the undercut portions.

18. The display panel of claim 13, wherein the organic material is an insulation material.

19. A display panel comprising:
a substrate on which a plurality of sub-pixels are defined;
a planarization layer disposed on the substrate and formed of insulation material;
a first electrode disposed on the planarization layer;
a light-emitting element layer disposed on the first electrode;
a second electrode disposed on the light-emitting element layer; and
a structure disposed between adjacent sub-pixels of the plurality of sub-pixels, the structure comprising undercut portions that disconnect the light-emitting element layer,
wherein the structure includes a first structure which is formed integrally with the planarization layer, and a second structure positioned on the first structure and electrically connected to the second electrode, and
wherein the undercut portions include a first undercut portion on a first side of the first structure and a second undercut portion on a second side of the first structure, in which portions of the planarization layer are recessed inward into the first undercut portion and into the second undercut portion.
